(19) United States
(12) Patent Application Publication
(10) Pub. No.: US 2008/0254578 A1
(43) Pub. Date: Oct. 16, 2008

(54) Method for fabricating thin film transistors

(75) Inventors: Chih-Jen Shih, Padeh City (TW); Wen-Chun Yeh, Padeh City (TW); Min-Che Ho, Padeh City (TW); Wen-Chi Yang, Padeh City (TW)

Correspondence Address: Joe McKinney Muncy, PO Box 1364, Fairfax, VA, 22038-1364, US

(73) Assignee: CHUNGHWA PICTURE TUBES, LTD

(21) Appl. No.: 11/882,539

(22) Filed: Aug. 2, 2007

(30) Foreign Application Priority Data
Apr. 13, 2007 (TW) 96113128

(51) Int. Cl. H01L 21/84

(52) U.S. Cl. 438/166; 257/E21.535

(57) ABSTRACT

A method for fabricating thin film transistors is disclosed. An amorphous silicon film is formed on a substrated and selectively irradiated with a laser beam for lateral growth to form a plurality of polysilicon regions. The whole surface of the substrate is then oxidized and irradiated with exicer laser annealing.

### BACKGROUND OF THE INVENTION

1. Field of the Invention

The present invention relates to the method for fabricating a thin film transistors, and more especially, to the method for fabricating the TFT by using the low temperature polysilicon technology.

2. Background of the Related Art

The fabrication technologies of the thin film transistor liquid crystal display (TFT LCD) include the polysilicon technique and the amorphous silicon technique. Now, the amorphous silicon technique is mature and widely used. The low temperature polysilicon technique (LTPS) is a newly fabricating process for the TFT LCD. The carrier mobility of the LTPS is two hundred times than the mobility of the amorphous silicon, and the difference between the traditional amorphous silicon display and the LTPS display is that the LTPS display has the advantages of high performance, high brightness and high resolution. If the LTPS display is applied to the notebook, the power of the notebook will be economized because of the low power consumption of the LTPS display.

FIG. 1 is an irradiating diagram of the conventional laser annealing technique. Recently, the traditional line beam excimer laser annealing (LBELA) technique is widely used, and in the LBELA technique, the flat-top excimer laser 10 is used to irradiate the whole glass substrate 20 repeatedly, and the scanning electron microscope (SEM) image of the polysilicon film is shown in the area A of the FIG. 1, wherein the grain size is about 0.3 millimeter (mm). The polysilicon which has been irradiated by the flat-top excimer laser 10 has the advantage of uniform electric performance to be suitable for the pixel TFT However, the component quality is not good enough to be applied in the high-density integrated periphery circuits on the panel edge.

Besides, in a lateral growth technique, a high-energy laser is used to irradiate a portion of an amorphous silicon substrate or whole amorphous silicon substrate for lateral growth, wherein the silicon within the laser irradiating area is melted completely, and the lateral un-melted silicon is applied as the seed to increase the grain size, so that the component area along the laser scan direction 25 expands to be beneficial for integrating the more periphery circuits on the panel edge. However, because the widths of the grains formed by the lateral growth technique are not uniform, the grain boundary may be forked or eliminated, as shown in the SEM image of FIG. 2, to cause the non-uniform electric performances and make the electric performances of the components perpendicular to the laser scan direction are poorer than the components parallel to the laser scan direction, to cause the troubling design for the circuit layout. The lateral growth technique includes the sequential lateral solidification (SLS) and the solid state laser (SSL).

Furthermore, the U.S. Pat. No. 6,949,452 discloses another growth technique, wherein the amorphous silicon film of whole substrate is irradiated by the LBELA, and then a portion of the substrate is irradiated by the SSL to make the grain size increasing. Although the SSL is applied effectively in this fabricating method, the last process of lateral growth still causes the poor uniformity of threshold voltage of the component, and the component differences between the perpendicular direction and the parallel direction still exist obviously.

### SUMMARY OF THE INVENTION

In order to solve the foregoing problems, one object of this invention is to apply the SLS or SSL technique to a portion of the substrate at first to perform the lateral growth and form a plurality of circuit areas, and then apply the LBELA technique to the whole area of the substrate, so as to widely promote the electric performance of the component, increase the component uniformity, and effectively fabricate the peripheral driving circuits on the panel edge, and furthermore to fabricate the System-On-Glass (SOG).

One object of this invention is to provide a method for fabricating thin film transistors, wherein a step of forming a thin oxidized layer on the substrate is added within the two laser irradiating steps, to eliminate the bias effect of the threshold voltage (Vth) caused by the second laser irradiation and furthermore to improve the interface stability between the polysilicon layer and the insulator.

Accordingly, one embodiment of the present invention provides a method for fabricating thin film transistors including: providing a substrate and forming an amorphous silicon film on the substrate; selectively irradiating a portion of the amorphous silicon film located in the substrate with a laser beam for lateral growth of the amorphous silicon film to form a plurality of polysilicon regions; oxidizing a surface of the substrate; and irradiating whole area of the substrate with excimer laser annealing.

### BRIEF DESCRIPTION OF THE DRAWINGS

FIG. 1 is an irradiating diagram of the conventional laser annealing technique;

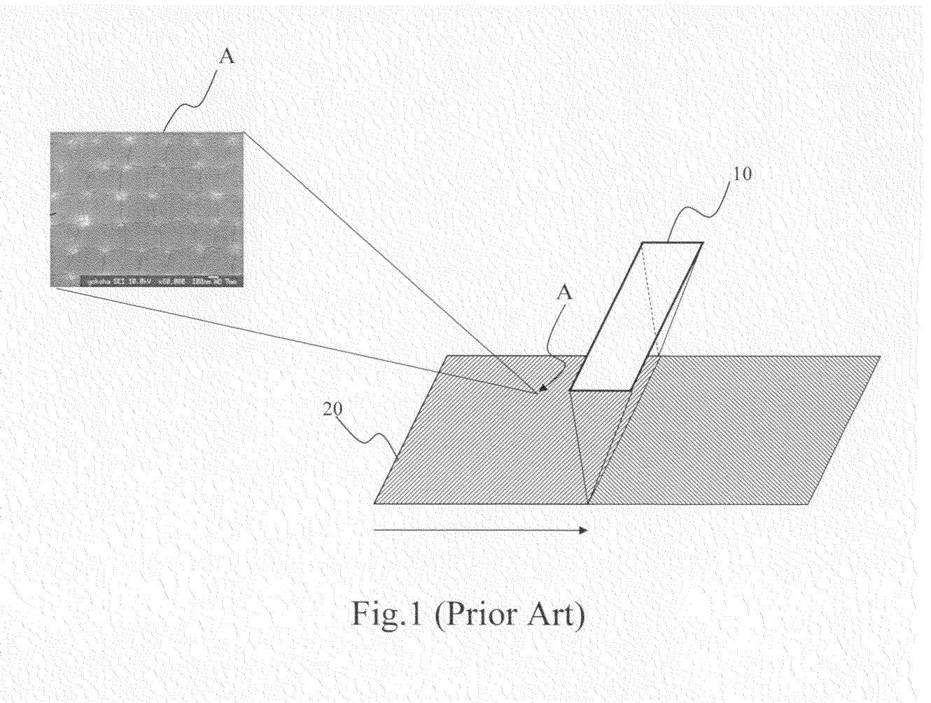

FIG. 2 is a scanning electron microscope image of the crystallization according to the conventional sequential lateral solidification;

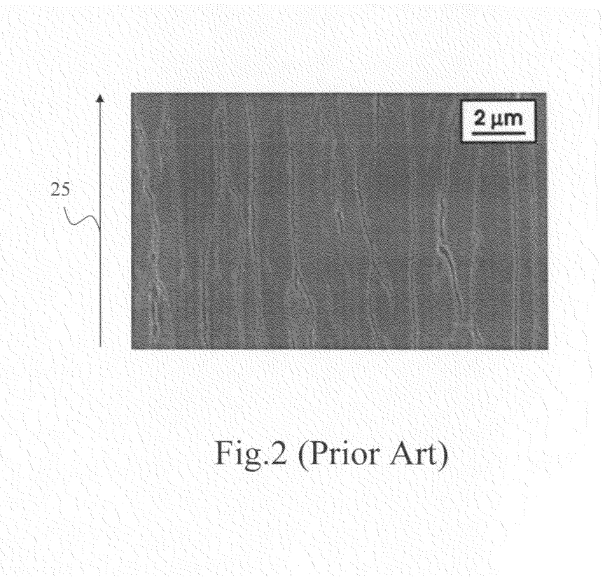

FIG. 3a and FIG. 3b are respectively a cross-sectional diagram and a vertical diagram illustrating an LTPS panel in accordance with an embodiment of the present invention;

FIG. 4 is a diagram illustrating the irradiating portion of the panel in accordance with the embodiment of the present invention;

FIG. 5 is a diagram illustrating the pixel structure in accordance with the embodiment of the present invention;

FIG. 6a is a scanning electron microscope image of the crystallization according to conventional lateral growth;

FIG. 6b is a scanning electron microscope image of the crystallization according to the present invention; and

FIG. 7a and FIG. 7b are respectively an electric performance diagram of the NMOS and an electric performance diagram of the PMOS.

### DETAILED DESCRIPTION OF THE INVENTION

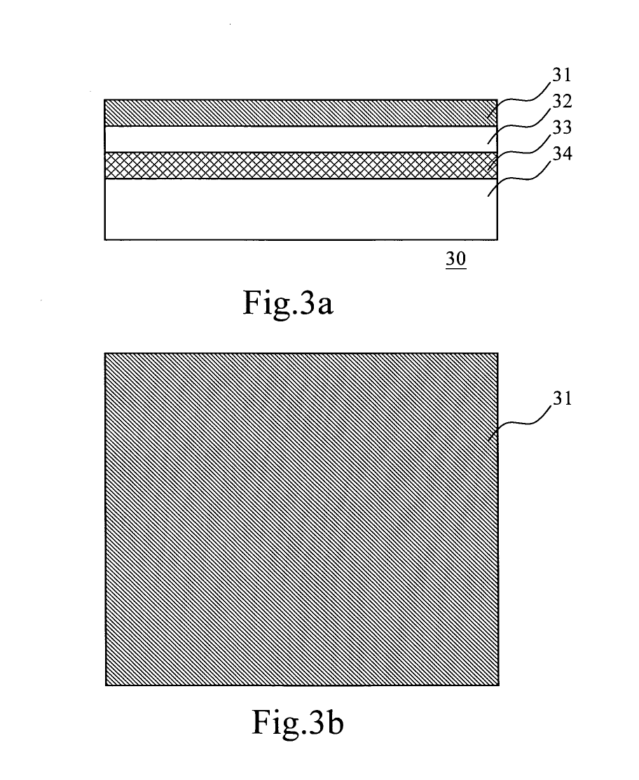

FIG. 3a and FIG. 3b are respectively a cross-sectional diagram and a vertical diagram illustrating an LTPS panel in accordance with an embodiment of the present invention. In the present embodiment, a substrate 30 is provided at first, wherein the bottom layer of the substrate 30 is a glass layer 34, and a silicon nitride (SiNx) film 33, a silicon oxide (SiOx) film 32 and an amorphous silicon (a-Si) film 31 are deposited on the glass layer 34 in order.

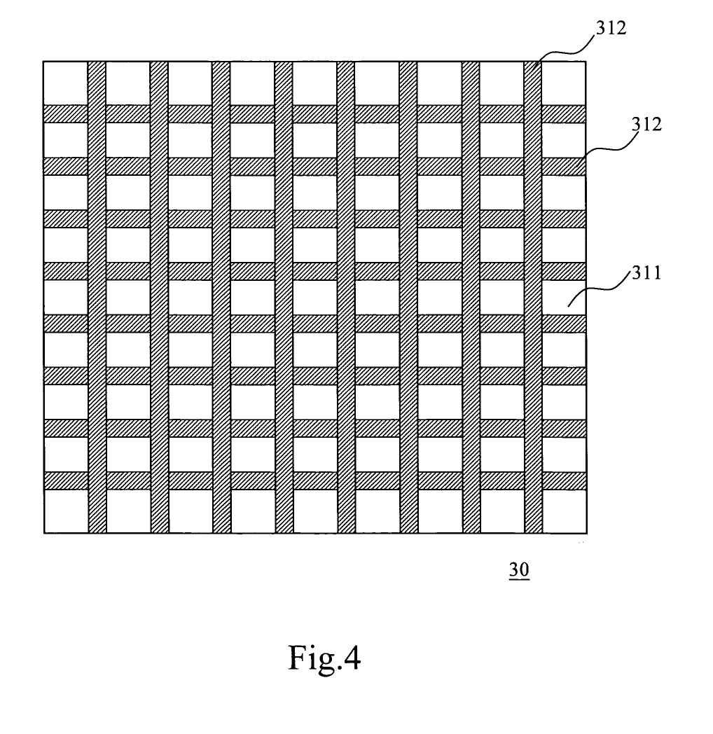

Next, please refer to FIG. 4 is a diagram illustrating the irradiating portion of the panel. In the process of crystal growing, the first laser irradiation is used to a portion 312 of the amorphous silicon film 31 to form a plurality of polysilicon regions, wherein the crystal growing technique is the laser annealing for lateral growth, such as the sequential lateral solidification (SLS), the solid state laser (SSL), or the thin beam directional crystallization (TDX), etc. In the following fabricating processes of LTPS, the portion 312 is the circuit area of the thin film transistors.

Then, the surface of the substrate 30 is oxidized by the following steps: cleaning the substrate with the dilute hydrogen fluoride (HF) solution and the ozonated (O₃) water, and then forming a compact oxidized layer on the surface of the substrate 30 by using high temperature and high pressure steam (or oxygen). Thus, the bias effect of the threshold voltage (Vth) caused by the following second laser irradiation can be eliminated because of the thin oxidized layer on the substrate, and furthermore to improve the interface stability between the polysilicon layer and the insulator.

Finally, the LBELA is proceeded for the whole area of the substrate, and the polysilicon regions formed on the first laser irradiating portion 312 are irradiated again to form a double-irradiated polysilicon, wherein the LCD pixel areas 311 are irradiated one time. After finishing the LBELA, the panel which is suitable for the LTPS technique is used to proceed to the following LTPS processes.

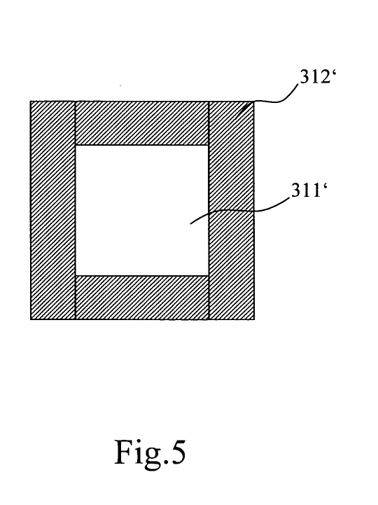

FIG. 5 is one of the pixel structures of the polysilicon panel according to the present invention, wherein the periphery is the circuit area 312′ which is irradiated two times, and the center is the pixel area 311′ which is irradiated one time by the LBELA.

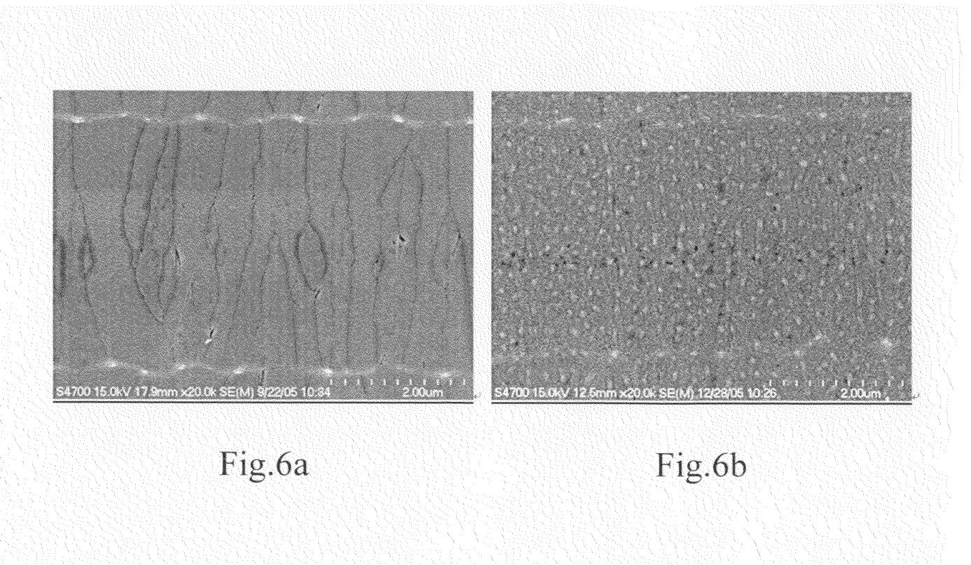

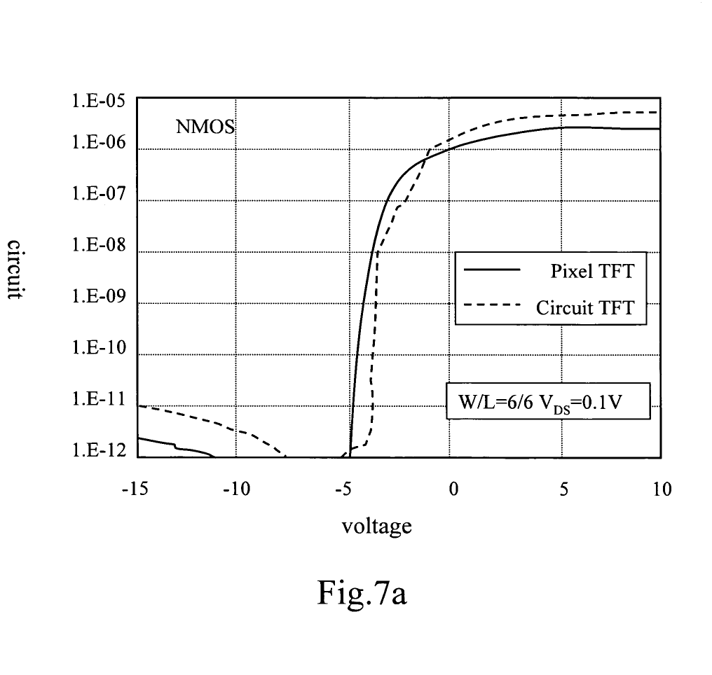

FIG. 6a is an SEM image of lateral growth and FIG. 6b is another SEM image of the crystallization according to the present invention. Refer to FIG. 6a and FIG. 6, the SEM images are different obviously.

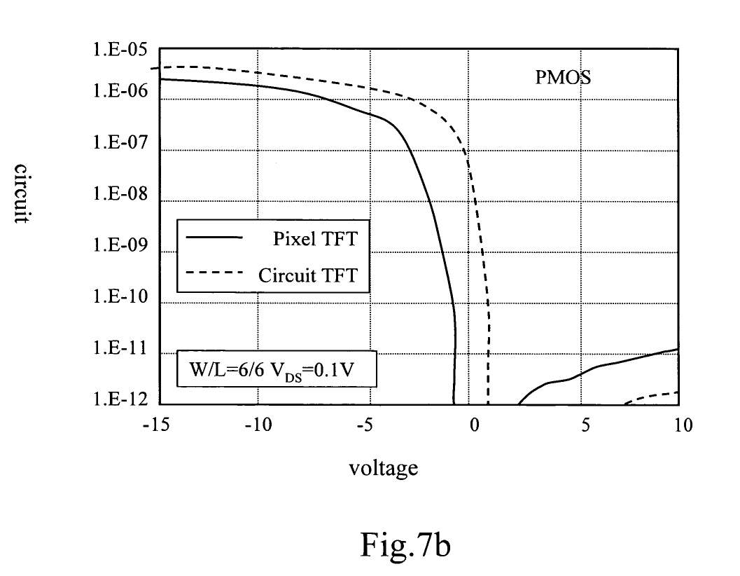

In one embodiment, the lateral growth is applied to an amorphous silicon substrate by the means of SLS, and then the LBELA is proceeded to the whole area of the substrate for crystallization to get the n-channel metal-oxide-semiconductor (NMOS) whose electric performance is shown in FIG. 7 a and the p-channel metal-oxide-semiconductor (PMOS) whose electric performance is shown in FIG. 7b. Furthermore, the Table1 and the Table2 respectively illustrate the electric performances of the NMOS and of the PMOS according to the perpendicular direction and the parallel direction relative to the grain boundary, and the values in the parenthesis represent the standard deviation of twelve measuring data.

TABLE 1

| | | TFT circuit | TFT circuit | TFT circuit |
|---|---|---|---|---|
| NMOS | Pixel TFT | (parallel, no LDD) | (parallel, LDD) | (perpendicular, LDD) |
| Vth (V) | 0.77 (0.12) | 1.01 | 1.66 (0.14) | 1.57 (0.15) |
| SS (V/Dec) | 0.28 (0.02) | 0.187 | 0.18 (0.04) | 0.25 (0.06) |
| Mobility (cm²/Vs) | 93 (6) | 331 | 210 (12) | 113 (5) |

TABLE 2

| | | TFT circuit | TFT circuit |
|---|---|---|---|
| PMOS | Pixel TFT | (parallel) | (perpendicular) |
| Vth (V) | −1.43 (0.25) | 1.64 (0.23) | 1.95 (0.80) |
| SS (V/Dec) | 0.35 (0.03) | 0.25 (0.04) | 0.44 (0.16) |
| Mobility (cm²/Vs) | 81 (5) | 128 (6) | 100 (5) |

It can be understood from the table1 and the table2 that the mobility of the circuit TFT fabricated by the method of the present invention is better than the mobility of the pixel TFT, and the uniformity of the electric performance of the circuit TFT has the same quality with the pixel TFT. Table 3 illustrates the electric performances of the components according to different fabricating methods, such as the conventional LBELA, SLS, the techniques of U.S. Pat. No. 6,949,452 and the present invention. As shown in Table 3, when the lateral growth technique, such as the SLS or SSL, is applied to the last fabricating process, the ratio of the mobility in perpendicular to the mobility in parallel is smaller than 0.4 for every NMOS, and the ratio of the mobility in perpendicular to the mobility in parallel is smaller than 0.5 for every PMOS, and so as to be unfavorable for circuit design. According to the fabricating method of the present invention, the ratio for every NMOS can reach 0.52 and the ratio for every PMOS can reach 0.78, and because both ratio are higher than the ratio in LBELA technique, the directions of the components in circuit area are not necessary to parallel the direction of the grain boundary, so that the circuit design is not limited

TABLE3

| | Tₛᵢ | | | | | | |
|---|---|---|---|---|---|---|---|
| | (nm) | N-μp | N-μv | P-μp | P-μv | N-μv/μp | P-μv/μp |
| LBELA | 45 | 168 | 168 | 83 | 83 | −1 | −1 |
| SLS | 45 | 220 | 80 | 106 | 48 | 0.36 | 0.45 |
| U.S. Pat. No. | 50 | 318 | 122 | 130 | NA | 0.38 | NA |
| 6949452 | | | | | | | |
| Present invention | 45 | 331 | 173 | 128 | 100 | 0.52 | 0.78 |

Tₛᵢ: the thickness of the polysilicon,
N-, P-: NMOS LTPS component, PMOS LTPS component, (W/L = 6/6 μm),
μv: the mobility of the component perpendicular to the grain boundary,
μp: the mobility of the component parallel to the grain boundary.

To sum up, in the present invention, the lateral growth is proceeded to the circuit area on the substrate, then the surface of the substrate is oxidized and finally the whole area of the substrate is proceeded by the LBELA, to widely promote the electric performance of the component, increase the component uniformity, and effectively fabricate the peripheral driving circuits on the panel edge, and furthermore to fabricate the SOG.

Although the present invention has been explained in relation to its preferred embodiment, it is to be understood that other modifications and variation can be made without departing the spirit and scope of the invention as hereafter claimed.

What is claimed is:

1. A method for fabricating thin film transistors, comprising:
(a) providing a substrate and forming an amorphous silicon film on the substrate;
(b) selectively irradiating a portion of the amorphous silicon film located in the substrate with a laser beam for lateral growth of the amorphous silicon film after the step (a), to form a plurality of polysilicon regions;
(c) oxidizing a surface of the substrate after step (b); and
(d) irradiating whole area of the substrate with excimer laser annealing after step (c).

2. The method for fabricating thin film transistors according to claim 1, wherein a silicon nitride film is formed between the substrate and the amorphous silicon film.

3. The method for fabricating thin film transistors according to claim 2, further comprising: forming a silicon oxide film on the silicon nitride film.

4. The method for fabricating thin film transistors according to claim 1, wherein the portion of the amorphous silicon film is a circuit area of the thin film transistors.

5. The method for fabricating thin film transistors according to claim 1, wherein in the step (b), a method of the lateral growth comprises sequential lateral solidification, solid state laser, or thin beam directional crystallization.

6. The method for fabricating thin film transistors according to claim 1, wherein in the step (d), the excimer laser annealing for the whole area comprises a line beam excimer laser annealing.

7. The method for fabricating thin film transistors according to claim 1, wherein the step of oxidizing the surface of the substrate comprises:
(a) cleaning the substrate by using a dilute hydrogen fluoride solution and an ozonated water; and
(b) forming an oxidized layer on the amorphous silicon film by using high temperature and high pressure steam after the step (a).
